(19) United States
(12) Patent Application Publication
(10) Pub. No.: US 2025/0393163 A1
(43) Pub. Date: Dec. 25, 2025

(54) TECHNIQUES FOR LIQUID COOLING MEMORY MODULES WITH NARROW PITCH

(71) Applicant: Intel Corporation, Santa Clara, CA (US)

(72) Inventors: Shaorong Zhou, Shanghai (CN); Chuanlou Wang, Shanghai (CN); Yingqiong Bu, Shanghai (CN); Yanbing Sun, Shanghai (CN); Ligang Wang, Beijing (CN)

(73) Assignee: Intel Corporation, Santa Clara, CA (US)

(21) Appl. No.: 19/313,127

(22) Filed: Aug. 28, 2025

(30) Foreign Application Priority Data
Jul. 2, 2025 (WO) PCT/CN2025/106703

(51) Int. Cl. H05K 7/20

(52) U.S. Cl. CPC H05K 7/20254; H05K 7/20272

(57) ABSTRACT

An apparatus includes a plurality of cold plate tubes spaced apart from each other, adjacent cold plate tubes defining a space for receiving a memory module, the plurality of cold plate tubes comprising thermally conductive material. A first manifold includes an inlet for a cooling fluid. A second manifold includes an outlet for the cooling fluid. The apparatus includes a first plurality of flexible hoses for fastening a first end of the plurality of cold plate tubes to the first manifold. The apparatus includes a second plurality of flexible hoses for fastening a second end of the plurality of cold plate tubes to the second manifold.

### RELATED APPLICATION

This application claims priority to PCT Application Serial No. PCT/CN2025/106703, filed Jul. 2, 2025, titled “TECHNIQUES FOR LIQUID COOLING MEMORY MODULES WITH NARROW PITCH”. The contents of the aforementioned application is incorporated herein by reference in its entirety.

### BACKGROUND

With the increasing demand for high-performance server systems in data centers, memory modules such as the DIMM (Dual-Inline Memory Module) are increasing in power while also becoming more compact with a narrower pitch. These changes in design and performance introduce significant challenges for liquid cooling systems for the memory modules that can also be assembled and disassembled for maintenance and serviceability of the memory modules. There is a need for a compact liquid cooling system for memory modules, such as DIMMs, that efficiently cool the memory modules and accommodate extremely narrow pitches while also providing access to service the memory modules.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A illustrates a perspective view of a liquid cooling system in accordance with one embodiment.

FIG. 1B illustrates an exploded view of a liquid cooling system in accordance with one embodiment.

FIG. 2 illustrates a cross-sectional view of a manifold and a cold plate tube in accordance with one embodiment.

FIG. 3 illustrates a schematic of a liquid cooling system showing a flow of the cooling liquid in accordance with one embodiment.

FIG. 4A illustrates a perspective view of a cold plate tube in accordance with one embodiment.

FIG. 4B illustrates a top cross-sectional view of a cold plate tube in accordance with one embodiment.

FIG. 4C illustrates an exploded view of a cold plate tube in accordance with one embodiment.

FIG. 5A illustrates a sectional view of a liquid cooling system with single-sided DIMMs in accordance with one embodiment.

FIG. 5B illustrates a sectional view of a liquid cooling system with single-sided DIMMs in accordance with one embodiment.

FIG. 6A illustrates a sectional view of a liquid cooling system with double-sided DIMMs in accordance with one embodiment.

FIG. 6B illustrates a sectional view of a liquid cooling system with double-sided DIMMs in accordance with one embodiment.

FIG. 7 illustrates an assembly process of a liquid cooling system for single-sided DIMMs in accordance with one embodiment.

FIG. 8 illustrates an assembly process of a liquid cooling system for double-sided DIMMs in accordance with one embodiment.

FIG. 9 illustrates a disassembly process of a liquid cooling system for single-sided DIMMs in accordance with one embodiment.

FIG. 10 illustrates a predicted maximum deformation of a cold plate tube with structural simulation in accordance with one embodiment.

### DETAILED DESCRIPTION

Embodiments are generally directed to liquid cooling techniques for thermal management of memory modules. Some embodiments are particularly directed to liquid cooling systems for narrow pitch memory modules, such as narrow pitch DIMMs. Data centers are complex systems in which multiple technologies and pieces of hardware interact to maintain safe and continuous operation of servers. With so many systems requiring power, the electrical energy used generates thermal energy. As the center operates, this heat builds and, unless removed, can cause equipment failures, system shutdowns, and physical damage to components. Much of this increased heat can be attributed to the operation of memory modules.

A liquid cooling architecture can include a plurality of cold plate tubes spaced apart from each other where adjacent cold plate tubes defining a space for receiving a memory module to receive a memory module between each cold plate tube, an ingress manifold with an inlet for a cooling liquid, and an egress manifold with an outlet for the cooling liquid. An inlet on a first end of the cold plate tubes and an outlet on an opposite second end of the cold plate tubes are respectively connected to the ingress and egress manifolds by flexible hoses to collectively form a path for the cooling liquid to flow through the cold plate tubes. The ingress and egress manifolds can each have joints extending from the manifolds and the inlets and outlets on the cold plate tubes can include joints extending from respective first and second ends of the cold plate tubes. The number of joints on each manifold can equal the number of cold plate tubes in the architecture. The flexible hoses can be fitted over joints to connect the manifolds to the cold plate tubes. Specifically, a first set of flexible tubes can be fitted over the joints on the ingress manifold and the joints on the inlets of the cold plate tubes. A second set of flexible tubes can be fitted over the joints on the egress manifold and the joints on the outlets of the cold plate tubes. Each joint can include at least one barb to secure the flexible hoses in place and sleeves can be fitted over each end of the flexible hoses for additional security. The joints of the manifolds can be oriented toward the cold plate tubes, and the flexible hoses can be oriented linearly between the cold plate tubes and respective manifolds for a compact height of the overall architecture. Alternatively, the joints of the manifolds can be oriented away from the cold plate tubes, and the flexible hoses can be bent to have a U-shape. The U-shape orientation provides a more compact length of the overall architecture. The flexible hoses provide are removably attached to the manifolds and cold plate tubes. The flexible hoses also provide sufficient movement among the parts for disassembly and reassembly to provide access to service the memory modules.

The cold plate tubes each include opposite planar surfaces with at least one planar surface including thermal interface material for an efficient exchange of thermal energy from the memory modules to the cooling liquid. The cold plate tubes are narrow to accommodate the narrow pitch of the memory modules. The narrow composition of the cold plate tubes causes the tubes to become susceptible to stress and flexing from a pressure by the cooling fluid flowing through the tubes. Each cold plate tube includes at least one internal rib fastened to interior sides of the opposite planar surfaces to provide sufficient structural integrity.

As memory modules become more compact with narrower pitches in smaller server chassis, more compact cooling solutions are needed. Heat pipe based cooling solutions are unable to support memory modules of high Thermal Design Power (TDP), such as 30 W or higher, while not exceeding a liquid inlet temperature boundary of 50° C. Traditional liquid cooling systems are rigid and cause assembly and disassembly tolerance issues and challenges for maintenance of the memory modules. The liquid cooling architecture described herein is sufficiently compact, efficient, and detachable to satisfy these demands.

As used herein, terms such as “top,” “bottom,” “upper,” “lower,” “back,” “front,” “above,” “below,” “under,” “lateral,” “medial,” “longitudinal,” “axial,” “radial,” etc., derivatives thereof, and words of similar import may be used herein to describe the relative placement and orientation of various components described herein, each with respect to the geometry and orientation of the components as they appear in the figures.

The present disclosure will now be described with reference to the attached drawing figures, wherein like reference numerals are used to refer to like elements throughout, and wherein the illustrated structures and devices are not necessarily drawn to scale.

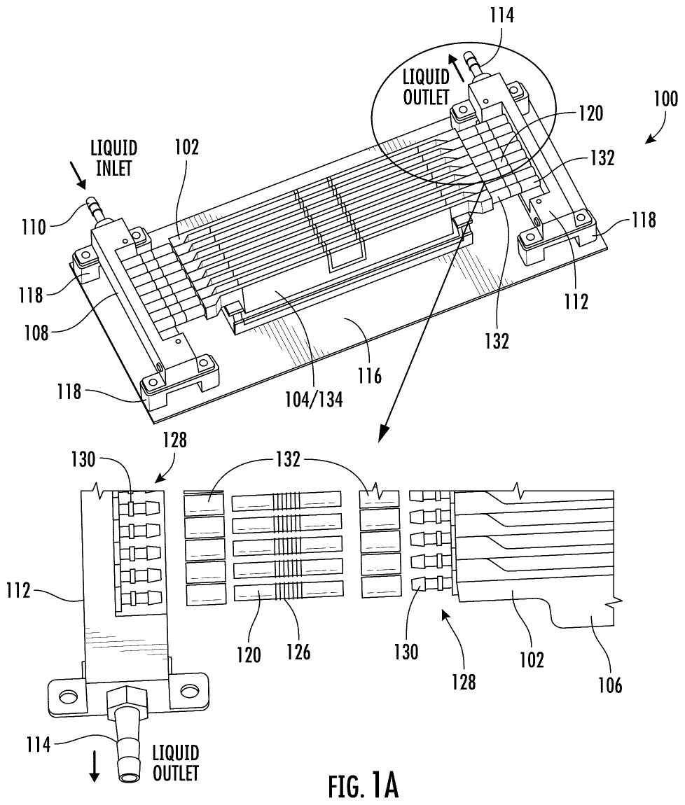

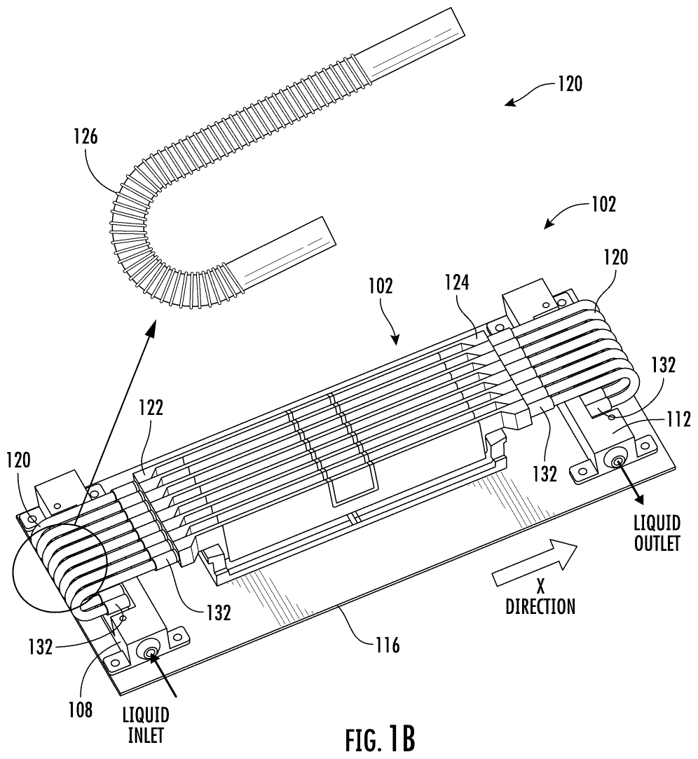

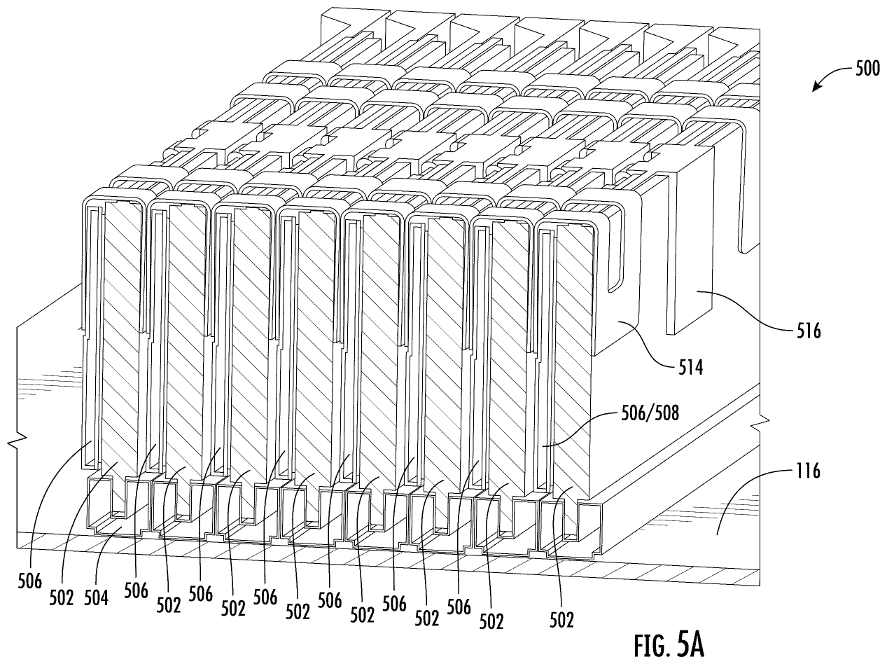

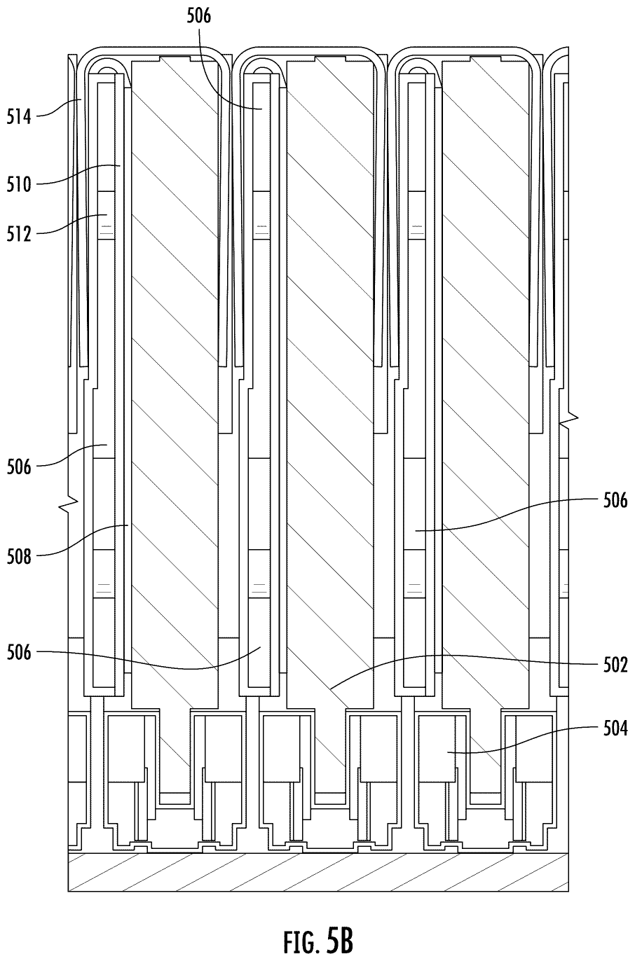

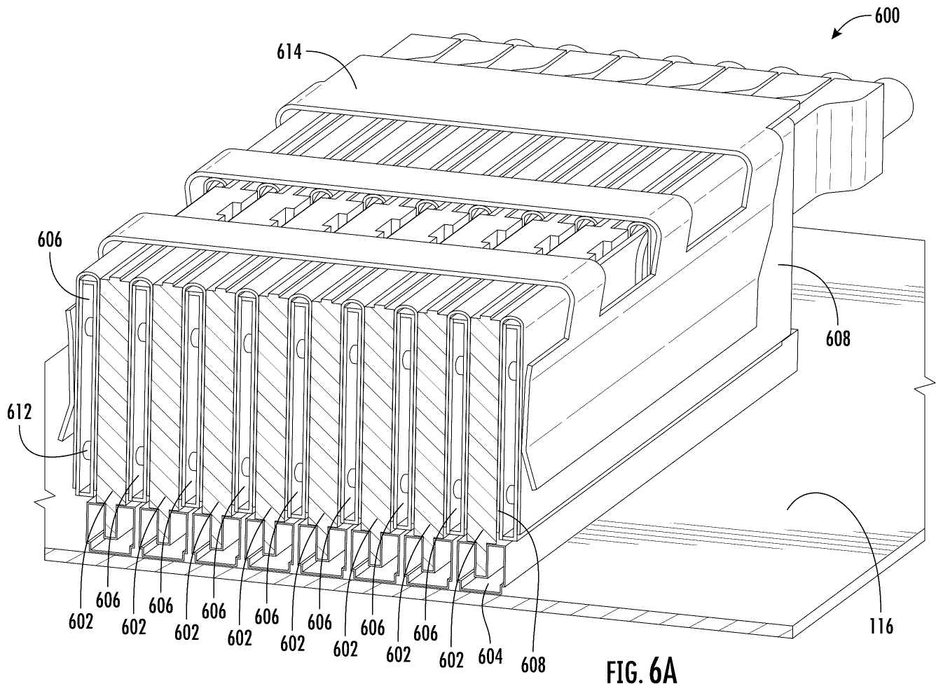

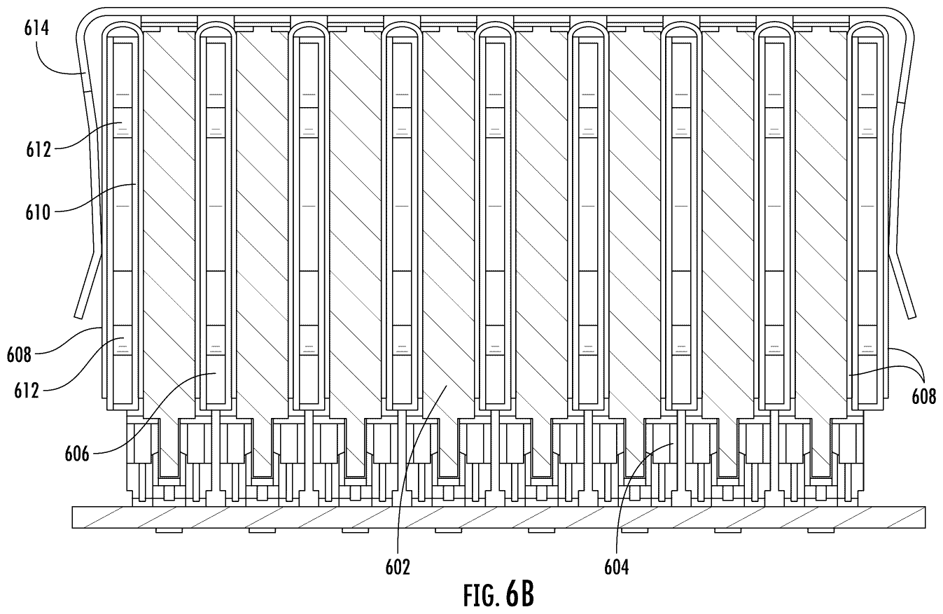

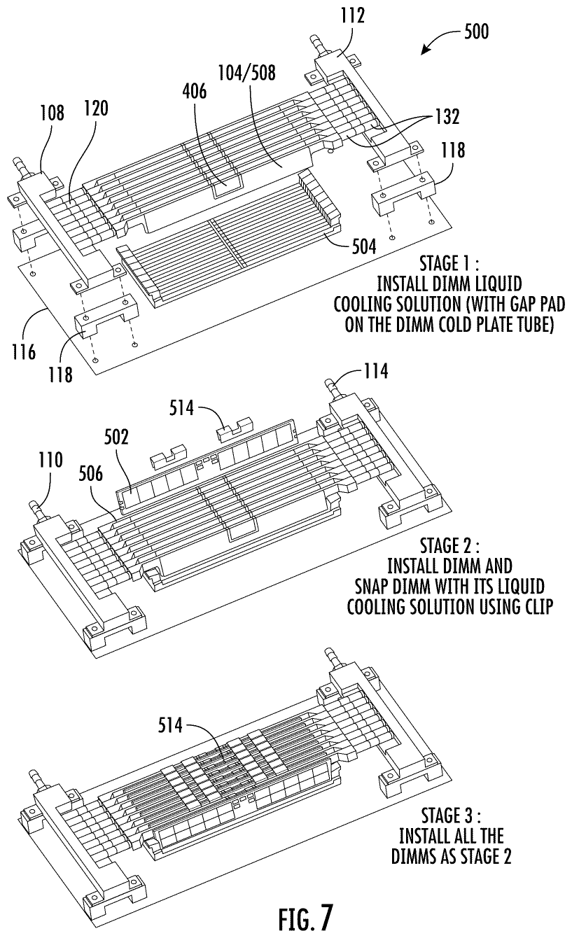

FIG. 1A illustrates a perspective view of a liquid cooling system 100 for memory modules and an exploded view of components of the system 100. The system 100 includes a plurality of cold plate tubes 102 each with a planar surface 104 on a front side and a planar surface 104 on an opposite back side, where at least one of the planar surfaces 104 abuts a memory module, as shown in FIGS. 5A-6B. The exploded view of the system shows a cover 106 on the cold plate tube 102. Each cold plate tube 102 includes a cover 106 on the planar surfaces 104. In some embodiments, the cover 106 is a single component on the cold plate tube 102 that wraps around a top and/or bottom of the cold plate tube 102 and forms both planar surfaces 104. In other embodiments, the cold plate tube 102 can include a first cover 106 expanding the front planar surface 104 and a second cover 106 expanding the back planar surface 104.

The cold plate tubes 102 are spaced apart from each other such that adjacent cold plate tubes 102 define a space for receiving a memory module, where each memory module abuts at least one cold plate tube 102, specifically at least one cover 106 of a cold plate tube 102. A cooling fluid is moved through the cold plate tubes 102 to cool the memory modules. The covers 106 can extend from a top of the cold plate tube 102 to the bottom of the cold plate tube 102. An interior surface of the covers 106 may directedly contact the cooling liquid. The cross-section of the cold plate tube 102 can be an elongated shape, for example a rectangle. The cold plate tube 102 can have a thickness of less than 4.0 mm, 4.25 mm, 4.5 mm, more than 4.5 mm, or any size in between. To accommodate narrow pitch memory modules, the cold plate tube 102 can have a thickness of 2.3 mm or smaller.

A memory module is a small circuit board with one or more memory chips, specifically random access memory (RAM) chips, and pins for connection to another circuit board, such as a motherboard. Examples of a memory module include a dual in-line memory module (DIMM), such as a single-sided DIMM and a double-sided DIMM. It is understood that the term single-sided DIMM as used herein refers to a DIMM with memory chips all on one side of the DIMM, and the term double-sided DIMM as used herein refers to a DIMM with memory chips on both sides of the DIMM. The memory modules can be connected to various types of computed devices including, without limitation, a central processing unit (CPU), graphics processing unit (GPU), data processing unit (DPU), vision processing unit (VPU), neural processing unit (NPU), infrastructure processing unit (IPU), tensor processing unit (TPU), and other processing units.

When in use, the memory modules produce excessive amounts of thermal energy and require cooling to prevent overheating, which can otherwise cause compromised performance or even damage of the memory modules. The liquid cooling architecture described herein can be implemented to liquid cool memory modules with a narrow pitch, such as 0.257 inches or less, with a high TDP, such as 35 W and higher, while remaining below a 50° C. liquid inlet temperature boundary. The liquid cooling architecture can operate at a pressure of at least 150 psi. Examples of liquid cooling architecture described herein can satisfy the spacing restrictions to cool a 16-channel DIMM, including single-sided DIMMs and double-sided DIMMs, in a 19-inch server chassis with a DIMM pitch of 0.257 inches. Accordingly, examples of memory modules described herein include eight DIMMs. It is understood that the liquid cooling architecture can also be implemented to cool fewer or more than eight memory modules, memory modules with various pitches, and different size configurations of server chassis. For example, the system 100 can include one, two, three, four, five, six, seven, eight, nine, or more cold plate tubes 102.

As a nonlimiting example, the system 100 including the systems 500 and 600 illustrated in FIGS. 5A-5B and 6A-6B, respectively, can provide a viable liquid cooling solution for single-sided and double-sided DIMMs with a high TDP of 30 W or higher and with 0.257 inches or less of pitch in a two-socket, sixteen-channel Intel® Xeon® based 19-inch server system. Thus, the system 100 can sufficiently provide liquid cooling for sixteen-channel DIMMs with a two-socket Intel® Xeon® CPU in a 19-inch server chassis.

Each cold plate tube 102 can include a thermal interface material (TIM) layer 134 on an exterior surface of at least one planar surface 104 of the cold plate tube 102. For example, cold plate tubes 102 configured for cooling single-sided DIMMs 502, as shown in FIG. 5A and FIG. 5B, may only have the TIM layer 134 on one planar surface 104 of each cold plate tube 102. In some embodiments, the TIM layer 134 can be on both opposite planar surfaces 104 of each cold plate tube 102. For example, cold plate tubes 102 configured for cooling double-sided DIMMs 602, as shown in FIG. 6A and FIG. 6B, may include the TIM layer 134 on both planar surfaces 104 of each cold plate tube 102 to cool a side of one DIMM adjacent to the front planar surface 104 and a side of another DIMM adjacent to the back planar surface 104. The TIM layer 134 can be a gap pad as described herein. Examples for the TIM layer 202 may comprise without limitation a polymer TIM (PTIM), an epoxy, a liquid phase sintering (LPS) paste, a solder paste, a solder TIM (STIM), and/or any other type of thermal interface material. The TIM layer 134 is located on the cold plate tube 102 where the cold plate tube 102 abuts the memory module, specifically one or both planar surfaces 104.

To accommodate the spacing restraints by the narrow pitch of memory modules the system 100 cools, the cold plate tube 102 can be thinner at the TIM layer 134 than at the first end 122 and the second end 124. In other words, the distance between the covers 106 can be less than the thickness of the cold plate tube 102 at its inlet and outlet. In some embodiments, neighboring cold plate tubes 102 can abut each other at the first ends 122 and the second ends 124, which can be the widest parts of the cold plate tubes 102, and the thinner sections of the cold plate tubes 102 at the covers 106 provide a space between the adjacent cold plate tubes 102 that can receive the memory module.

The cold plate tubes 102 are positioned between a first manifold 108 and a second manifold 112. The first manifold 108 includes an inlet 110 for the cooling liquid and the second manifold 112 includes an outlet 114 for the cooling liquid. The first manifold 108 and the second manifold 112 each include a cavity for holding a cooling liquid, which is also a conduit for the flow of a cooling liquid. The cold plate tubes 102 each have an inlet at a first end 122 to receive the cooling liquid from the first manifold 108 and an outlet at a second end 124 opposite the first end 122 to expel the cooling liquid to the second manifold 112. The first manifold 108 and the second manifold 112 can be mounted to a mounting surface, such as a printed circuit board (PCB) 116, directly or indirectly. For example, the first manifold 108 and the second manifold 112 can be fastened to one or more stands 118 that are fastened to the PCB 116, where the stands 118 elevate the first manifold 108 and second manifold 112 from the PCB 116.

Flexible hoses 120 provide conduits between the first manifold 108, the cold plate tubes 102, and the second manifold 112. A first set of the flexible hoses 120 connects the first ends 122 of the cold plate tubes 102 to the first manifold 108. A second set of the flexible hoses 120 connects the second ends 124 of the cold plate tubes 102 to the second manifold 112. The flexible hoses 120 can include at least one corrugated section 126 with parallel ridges and groove for improved flexibility. In an example embodiment, each flexible hose 120 includes at a center of the hose a corrugated section 126, where at least a portion of the flexible hose 120 on either side of the corrugated section 126 is not corrugated. The flexible hoses 120 can comprise material including polytetrafluoroethylene (PTFE), plastic, ceramic, and the like. In an example embodiments, the flexible hoses 120 can have an outer diameter of 4.0 mm and in inner diameter of 2.0 mm. The flexible hoses 120 can have an outer diameter of less than 3.8 mm, 3.8 mm, 3.9 mm, 4.0 mm, 4.1 mm, 4.2 mm, 4.3 mm, 4.4 mm, 4.5 mm, 4.6 mm, more than 4.6 mm, and any size in between and an inner diameter of less than 1.8 mm, 1.8 mm, 1.9 mm, 2.0 mm, 2.1 mm, 2.2 mm, 2.3 mm, 2.4 mm, 2.5 mm, more than 2.5 mm, and any size in between.

The first manifold 108 and the second manifold 112 can have joints 128 extending from the manifolds. The inlets on the first end 122 of the cold plate tubes 102 and the outlets on the second end 124 of the cold plate tubes 102 can include joints 128 extending from the respective ends of the cold plate tubes 102. The number of joints 128 on each of the first manifold 108 and the second manifold 112 can equal the number of cold plate tubes 102 in the system 100. The example embodiments of system 100 shown in FIG. 1A includes eight joints 128 on each of the first manifold 108 and the second manifold 112 to connect to the corresponding eight cold plate tubes 102. It is understood that system 100 can include fewer or more cold plate tube 102 and corresponding joints on the first manifold 108 and the second manifold 112, for example one, two, three, four, five, six, seven, eight, nine, or more.

The flexible hoses 120 can be fitted over the joints 128 to connect the first manifold 108 and the second manifold 112 to the cold plate tubes 102. Specifically, ends of a first set of flexible hoses 120 can be fitted over the joints 128 on the first manifold 108 and opposite ends of the first set of flexible hoses 120 can be fitted over the joints 128 on the first ends 122 of the cold plate tubes 102. Ends of a second set of flexible hoses 120 can be fitted over the joints 128 on the second manifold 112 and opposite ends of the second set of flexible hoses 120 can be fitted over the joints 128 on the second ends 124 of the cold plate tubes 102. Each joint 128 can include at least one barb 130 to secure the flexible hoses 120 in place. The barbs 130 can extend axially from the joints 128. The barb 130 may extend from the joints 128 at an angle and/or include at least one angled surface. Sleeves 132 can be fitted over each end of the flexible hoses 120 for additional security. The sleeves 132 can comprise a hollow cylindrical shape. An inner diameter of the sleeves 132 is larger than an outer diameter of the joints 128. In some embodiments, an interior surface of the sleeves 132 can include rivets or bumps to secure the flexible hoses 120 in place. In the example configuration shown in FIG. 1A, the flexible hoses 120 extend linearly between the first manifold 108 and the cold plate tubes 102 and between the cold plate tubes 102 and the second manifold 112.

The first manifold 108, the joints 128 on the first manifold 108, the sleeves 132, the cold plate tubes 102, the joints 128 on the cold plate tubes 102, the second manifold 112, and/or the joints 128 on the second manifold 112 may be formed of a highly thermally conductive material, such as copper, aluminum, steel, e.g., SUS304, or the like.

A fluid pump moves the cooling liquid into the inlet 110 of the first manifold 108 and through the joints 128 of the first manifold 108. The cooling liquid flows from the joints 128 of the first manifold 108, through the first set of flexible hoses 120, through the joints 128 at inlets of the first ends 122 of the cold plate tubes 102, and into the cold plate tubes 102. While the cooling liquid is flowing through the cold plate tubes 102, thermal energy that has been transferred from the memory modules to the cold plate tubes 102 is transferred to the cooling liquid. The cooling liquid then flows out of the cold plate tubes 102 through the joints 128 at outlets of the second ends 124 of the cold plate tubes 102, through the second set of flexible hoses 120, through the joints 128 of the second manifold 112, and into the second manifold 112. The cooling liquid, which has been warmed by the thermal energy received from the cold plate tubes 102 is expelled from the second manifold 112 through the outlet 114. In some embodiments, the warmed cooling liquid expelled from the second manifold 112 through the outlet 114 can flow to a cooling component, for example and without limitation, heat exchangers, condensers, heat pumps, and the like, for cooling and be recycled to the inlet 110 of the first manifold 108. In other embodiments, the cooling liquid is cycled through the cold plate tubes 102 only once. The cooling liquid can be cycled through the cold plate tube 102 at different rates including less than 0.6 revolutions per minute (rpm), 0.6 rpm, 0.7 rpm, more than 0.7 rpm, and any rate in between.

As described herein, the cooling fluid may receive heat from the cold plate tube 102, which can dissipate heat from the heated liquid into the ambient, or another separate liquid cooling component or system. Examples of the cooling fluid include engineered fluids such as 3M™ Novec™ and Fluorinert™, synthetic oils, and specially formulated dielectric fluids. These fluids have high thermal conductivity and are electrically insulating. Two parameters of the cooling fluid to consider when choosing a cooling fluid for use in a particular cooling implementation are its flammability and global warming potential (GWP) number, with a lower GWP number indicating that a material contributes less to global warming. Some synthetic single-phase cooling liquids (e.g., Novec fluids) have good thermal performance but also have a high GWPs. As there are worldwide efforts to phase out the use of greenhouse gases, such as hydrofluorocarbons, there is interest in using non-GWP or low-GWP materials (e.g., materials having a GWP<1) where possible. The liquid cooling technologies disclosed herein can provide for the liquid cooling of electronic devices and systems comprising high-performance IC components using non-flammable and/or non-GWP or low-GWP fluids. The use of such technologies can aid large cloud service providers (CSPs), high-performance computing (HPC) system vendors, and other entities that may begin to increasingly rely on liquid cooling in data centers to meet defined environmental sustainability (e.g., carbon-neutral, carbon-negative) goals.

In one embodiment, the cooling fluid is a non-electric-conductive, non-ionic, and non-reactive liquid (e.g., a fluorinated liquid). In another embodiment, the cooling fluid may be water. In some embodiments, the cooling fluid may be a fluorinated liquid type and/or a freon liquid type. Examples of a fluorinated liquid type may include without limitation FC-3283, FC-40, FC-43, FC-72, FC-75, FC-78, and FC-88. In one embodiment, for example, the freon liquid type may include freon-C-51-12, freon-E5, or freon-TF. Embodiments are not limited to these examples.

FIG. 1B illustrates the system 100 with an alternative configuration of the flexible hoses 120. In this example, the flexible hoses 120 have a U-shape and are positioned such that the ends of each flexible hose 120 are oriented in the same direction. As shown in FIG. 1B, the joints 128 of the first manifold 108 and the joints 128 of the first end 122 of the cold plate tubes 102 are extending in the same direction, where the joints of the first manifold 108 are directed away from the cold plate tubes 102. Similarly, the joints 128 of the second manifold 112 and the joints 128 of the second end 124 of the cold plate tubes 102 are extending in the same direction, where the joints 128 of the second manifold 112 are directed away from the cold plate tubes 102. The first set and the second set of the flexible hoses 120 have an end attached to the respective first manifold 108 and second manifold 112. The first set of the flexible hoses 120 are bent over the first manifold 108 and the opposite end of the first set of flexible hoses 120 are attached to the first end 122 of the cold plate tubes 102. The second set of the flexible hoses 120 are bent over the second manifold 112 and the opposite end of the second set of flexible hoses 120 are attached to the second end 124 of the cold plate tubes 102. The flexible hoses 120 can be bent to have a U-shape at the corrugated section 126 of the flexible hoses 120.

This configuration reduces the overall length of the system 100 and provides a cooling solution for environments, such as server racks, with limited available space for the length of the system 100. The PCB 116 in this configuration can also have a reduced length compared to the PCB 116 in the configuration shown in FIG. 1A. In some embodiments, to reconfigure the orientation of the joints 128 extending from the first manifold 108 and the second manifold 112 between the orientation shown in FIG. 1A and the orientation shown in FIG. 1B, the first manifold 108 and the second manifold 112 can be rotated 180 degrees. In other embodiments, the locations of the first manifold 108 and the second manifold 112 can be exchanged. In some embodiments, the flexible hoses 120 in the U-shaped orientation shown in FIG. 1B are longer than the flexible hoses 120 in the linear orientation shown in FIG. 1A. In other embodiments, the flexible hoses 120 shown in FIG. 1B are the same length as the flexible hoses 120 shown in FIG. 1A.

The liquid cooling system 100 can includes the embodiments of liquid cooling systems described herein, include the system 500 and the system 600 illustrated in FIGS. 5A-5B and FIGS. 6A-6B. For example, the cold plate tube 102 can include the cold plate tube 506 and the cold plate tube 606, and the memory modules described in system 100 can include the single-sided DIMMs 502 described in system 500 and the double-sided DIMMs 602 described in system 600.

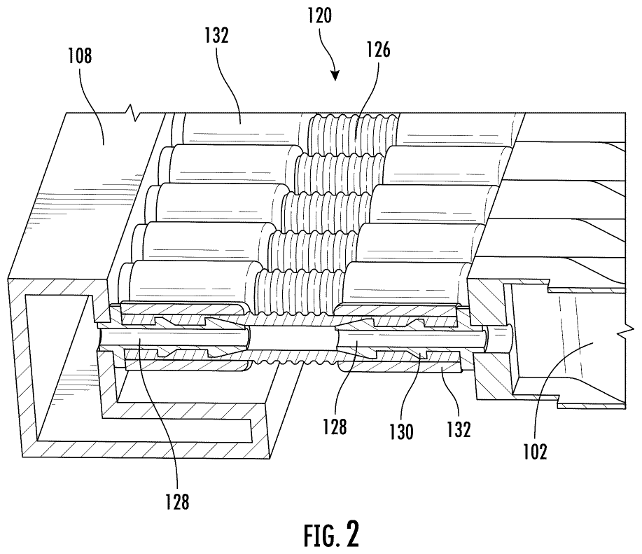

FIG. 2 illustrates a cross-sectional view of the first manifold 108 and a cold plate tube 102. Although not shown, it is understood that the connections between the second manifold 112 and the cold plate tubes 102 correspond to the connections between the first manifold 108 and the cold plate tubes 102 shown in FIG. 2. FIG. 2 shows flexible hoses 120 oriented linearly similarly to the configuration shown in FIG. 1A. In this configuration, the joints 128 on the first manifold 108 are aligned with respective joints 128 on the cold plate tubes 102. The joints 128 can include a hollow cylindrical shape such as a pipe. An exterior surface of the joints 128 can include rivets or bumps to increase friction with the flexible hoses 120. Each joint 128 can include a collar that extends radially from the joint 128. The collar can locate and abut an end of a flexible hose 120. Each joint 128 can include one, two, three, or more barbs 130 to secure the flexible hoses 120 in place over the joints 128. The barbs 130 can extend axially from the joints 128. The barb 130 may extend from the joints 128 at an angle and/or include at least one angled surface.

A first end of a flexible hose 120 is fitted over a joint 128 of the first manifold 108 and an opposite second end of the flexible hose 120 is fitted over a respective joint 128 of the cold plate tube 102. A sleeve 132 can be fitted over the first end of the flexible hose 120 and the joint 128 of the first manifold 108. Another sleeve 132 can be fitted over the second end of the flexible hose 120 and the joint 128 of the cold plate tube 102. In some embodiments, the corrugated section 126 of the flexible hose 120 can remain fully uncovered by the sleeves 132, partially covered by one or both sleeves 132, or fully covered by one sleeve 132 or a combination of both sleeves 132.

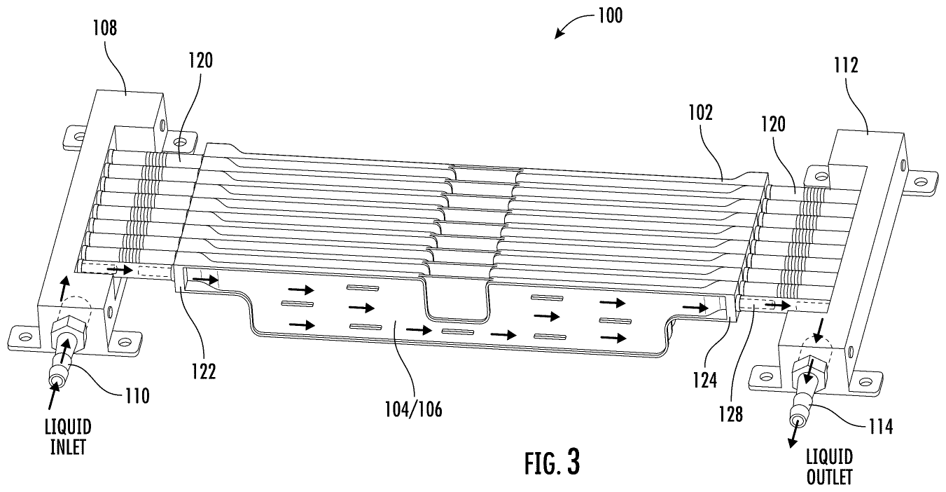

FIG. 3 illustrates a schematic of the system 100. In FIG. 3, the system 100 is shown without the TIM layer 134 and without the sleeves 132 to illustrate the flow of the cooling liquid through the system 100. A fluid pump moves the cooling liquid into the inlet 110 of the first manifold 108 and through the joints 128 of the first manifold 108. The cooling liquid flows from the joints 128 of the first manifold 108, through the first set of flexible hoses 120, through the joints 128 at inlets of the first ends 122 of the cold plate tubes 102, and into the cold plate tubes 102. While the cooling liquid is flowing through the cold plate tubes 102, thermal energy that has been transferred from the memory modules to the cold plate tubes 102 is transferred to the cooling liquid. The cooling liquid then flows out of the cold plate tubes 102 through the joints 128 at outlets of the second ends 124 of the cold plate tubes 102, through the second set of flexible hoses 120, through the joints 128 of the second manifold 112, and into the second manifold 112. The cooling liquid, which has been warmed by the thermal energy received from the cold plate tubes 102 is expelled from the second manifold 112 through the outlet 114.

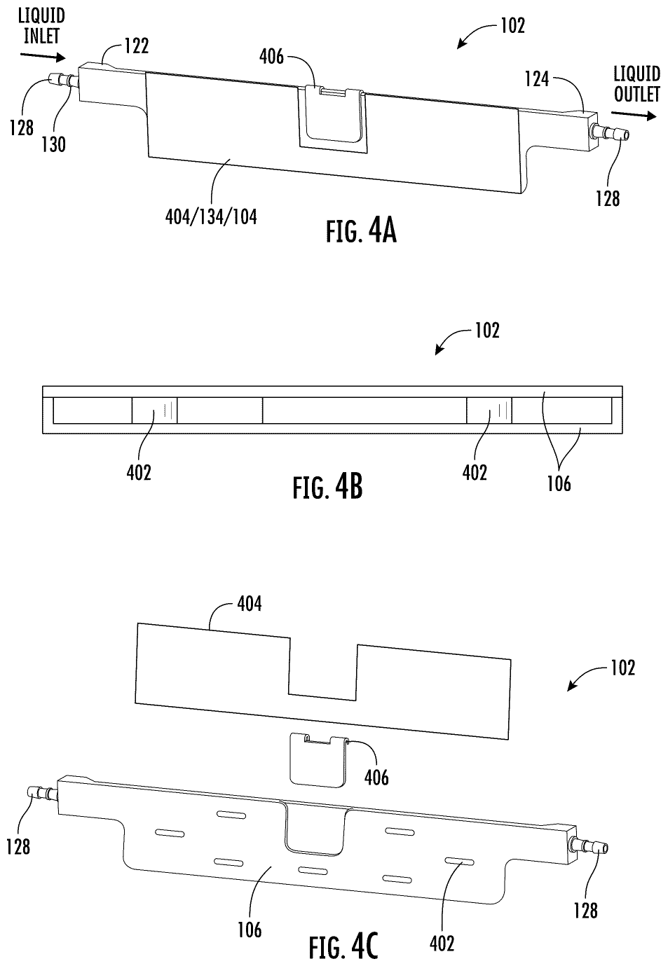

FIG. 4A, FIG. 4B, and FIG. 4C respectively illustrate a perspective view, top cross-sectional view, and exploded view of the cold plate tube 102. The cooling liquid flows into the inlet through the joint 128 at the first end 122, travels the length of the cold plate tube 102, and exits the outlet through the joint 128 at the second end 124. The cold plate tube 102 includes one or more ribs 402 that extend between the covers 106 of the cold plate tube 102. The ribs 402 connect the covers 106 at the planar surfaces 104 to enhance the structural strength of the cold plate tube 102. While in use, the covers 106 can be susceptible to flexing from the high fluid pressure exerted by the flow of the cooling liquid through the cold plate tube 102, which could result in gaps between the cold plate tube 102 and the memory module, reducing the efficiency at which thermal energy is transferred from the memory module to the cold plate tube 102. The ribs 402 reduce or prevent the flexing and ensure the covers 106 remain planar. The ribs 402 can be perpendicular to the covers 106. The ribs 402 may connect the covers 106 at an angle. In some embodiments, the ribs 402 extend at least partially into the covers 106. The ribs 402 may extend fully through the covers 106 to an exterior surface of the covers 106, as shown in FIG. 4C. Each cold plate tube 102 can include one, two, three, four, five, six, seven, eight, nine, or more ribs 402. The ribs 402 can have a cross-section that is elongated parallel to the length of the cold plate tube 102 to reduce the impedance to fluid flow through the cold plate tube 102. Examples of the shape of the elongated cross-section of the ribs 402 can include an oval, ellipse, rectangle, and the like. The cold plate tube 102 with ribs 402 can be manufactured using, for example, additive manufacturing, such as three dimensional (3D) printing, subtractive manufacturing, computer numerical control (CNC) machining, and brazing.

Each cold plate tube 102 includes at least one gap pad 404. The gap pad 404 can be removable from the cold plate tube 102. The gap pad 404 can include a Power Management Integrated Circuit (PMIC) gap pad 406 with a height on the cold plate tube 102 different than a height of the rest of the gap pad 404 to accommodate the different height of the PMIC 516 compared to the rest of the memory module, as shown in FIG. 5A. The PMIC gap pad 406 can have a different thickness than the gap pad 404 such that a surface of the PMIC gap pad 406 is not co-planar with the gap pad 404.

FIG. 5A and FIG. 5B illustrate a sectional view and a side view of a liquid cooling system 500 with single-sided DIMMs 502. The PCB 116 includes a socket 504 on the PCB 116 for each single-sided DIMM 502. In the example embodiment shown, the single-sided DIMMs 502 have a pitch of 0.257 inches with an available space between adjacent single-sided DIMMs 502 for a liquid cooling solution of 2.8 mm. As the DIMMs shown are single-sided, one cold plate tube 506 abuts one side of each of the single-sided DIMMs 502, which are held together by a clip 514 over a top portion of the paired cold plate tube 506 and single-sided DIMM 502. Accordingly, the cold plate tube 506 may include the gap pad 508 on only one cover 510, namely the cover 510 abutting the paired single-sided DIMM 502. The example embodiment of the cold plate tube 506 shown in FIG. 5A and FIG. 5B includes a gap pad 508 that is 0.2 mm thick, opposite covers 510 each 0.4 mm thick, and ribs 512 that extend 1.0 mm between the covers 510. The sum of these measurements plus the thickness of two clips 514 each 0.4 mm thick totals 2.8 mm. The thickness of the gap pad 508, covers 510, ribs 512, and clips 514 can vary to satisfy pitches that provide less or more spacing than 2.8 mm.

FIG. 6A and FIG. 6B illustrate a sectional view and a side view of a liquid cooling system 600 with double-sided DIMMs 602. The PCB 116 includes a socket 604 on the PCB 116 for each double-sided DIMM 602. In the example embodiment shown, the double-sided DIMMs 602 have a pitch of 0.257 inches similar to the pitch of the single-sided DIMMs 502 shown in FIG. 5A and FIG. 5B and so the available space between adjacent double-sided DIMMs 602 for a liquid cooling solution is also 2.8 mm. However, as the DIMMs are double-sided DIMMs 602, a gap pad 608 is on both covers 610 to cool a side of a double-sided DIMM 602 abutting one side of the cold plate tube 606 and a side of another double-sided DIMM 602 abutting the other side of the cold plate tube 606. Each cold plate tube 606 in this embodiment, besides the cold plate tubes 606 at the ends, abut two double-sided DIMMs 602 rather than pairing with a single DIMM. Accordingly, a single clip 614 is placed over a top portion of all the cold plate tubes 606 and the double-sided DIMMs 602 to hold them in place together. In some embodiments, the cold plate tubes 606 at the ends may only include the gap pad 608 on one side, namely the side abutting the double-sided DIMM 602. The example embodiment of the cold plate tube 606 shown in FIG. 6A and FIG. 6B includes a gap pad 608 that is 0.25 mm thick on each side, opposite covers 610 each 0.5 mm thick, and ribs 612 that extend 1.3 mm between the covers 610. The sum of these measurements totals 2.8 mm. The thickness of the gap pad 608, covers 610, and ribs 612 can vary to satisfy pitches that provide less or more spacing than 2.8 mm. The total thickness of the components can equal the available spacing between adjacent memory modules to maximize contact between the memory modules and the cold plate tubes 102, such as the cold plate tubes 506 and the cold plate tubes 606.

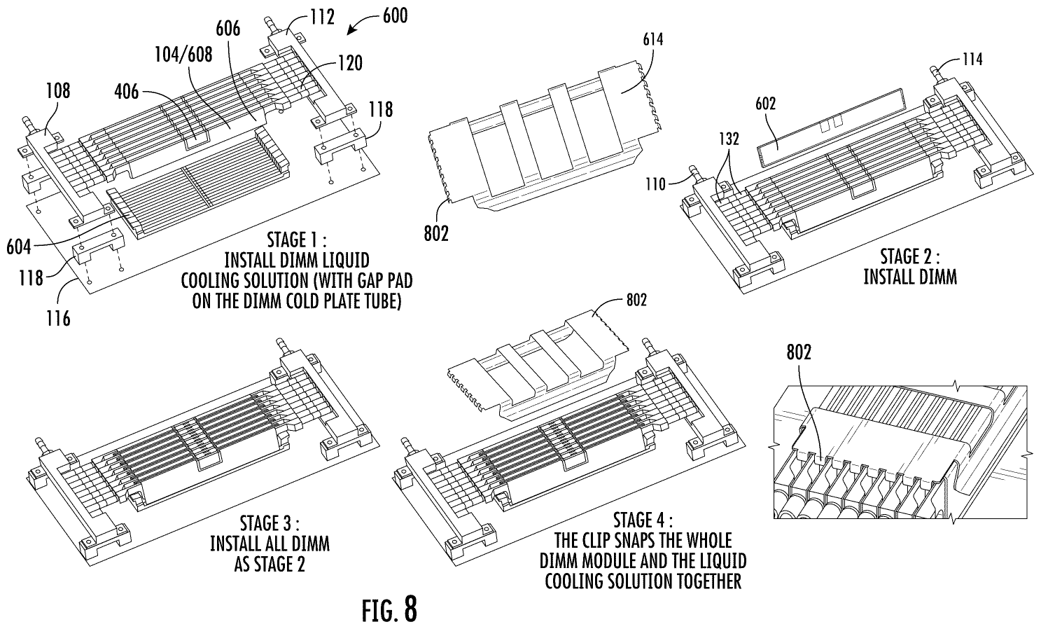

FIG. 7 illustrates an assembly process of the system 500 for single-sided DIMMs 502. At Stage 1, the cold plate tubes 506 are installed on the PCB 116. The sockets 504 for the single-sided DIMMs 502 are already attached to the PCB 116. As described herein, the single-sided DIMMs 502 may have a pitch of 0.257 inches or less. Each cold plate tube 506 has the gap pad 508, which can include the PMIC gap pad 406, on one planar surface 104 of the cold plate tube 506.

The cold plate tubes 506 are connected to the first manifold 108 and the second manifold 112 by the flexible hoses 120, and the sleeves 132 secure the ends of the flexible hoses 120 in place. For installing the first set of flexible hoses 120, a first end of each flexible hose 120 can be connected to the first manifold 108 or the cold plate tube 506 by inserting the joint 128 of the first manifold 108 or the cold plate tube 506 into the first end of the flexible hose 120, as shown in FIG. 1A. A sleeve 132 can be fitted over the first end of each of the first set of flexible hoses 120 to secure the flexible hoses 120 in place. Another sleeve 132 can be fitted onto the second end of each first set of flexible hoses 120 and slid past the second end of the flexible hoses 120 as the joint 128 of the cold plate tube 506 or the first manifold 108 is inserted into the second end. Then the sleeve 132 can be slid forward over the second end of the flexible hose 120 to secure the second end in place. The same process can be performed for connecting the cold plate tubes 506 to the second manifold 112.

The first manifold 108 and the second manifold 112 are then fastened directly or indirectly to the PCB 116, being positioned in relation to the sockets 504 such that the single-sided DIMMs 502 would be positioned between the cold plate tubes 506. In some embodiments, the first manifold 108 and the second manifold 112 can be fastened to stands 118, which are in turn fastened to the PCB 116.

At Stage 2, a first single-sided DIMM 502 is inserted into the socket 504 between the back two cold plate tubes 506, which are the nearest cold plate tube 506 and the second nearest cold plate tube 506 to the inlet 110 and the outlet 114. In this example configuration, the side of the single-sided DIMM 502 with the memory chips is the side facing the inlet 110 and the outlet 114 and, therefore, abuts the gap pad 508 on the cold plate tube 506 nearest the inlet 110 and the outlet 114. At least one clip 514 is snapped over a top portion of the single-sided DIMM 502 and the cold plate tube 506 nearest the inlet 110 and the outlet 114 for improved and maintained contact between the single-sided DIMM 502 and the cold plate tube 506. One, two, three or more clips 514 can be fitted onto each pair of single-sided DIMM 502 and cold plate tube 506.

At Stage 3, the remaining single-sided DIMMs 502 are inserted into respective sockets 504 similarly to Stage 2. The cold plate tubes 506 and the single-sided DIMMs 502 are positioned in alternating order. At least one clip 514 is snapped over a top portion of each pair of single-sided DIMM 502 and cold plate tube 506 in which the gap pad 508 abuts the side of the single-sided DIMM 502 with the memory chips. It is understood that the single-sided DIMMs 502 can be inserted into their corresponding sockets 504 in any order and that the back single-sided DIMM 502 selected as the first for placement in Stage 2 is simply an illustrative example. As the DIMMs cooled in the system 500 are single-sided, only one side of the single-sided DIMM 502 may abut the cold plate tube 506 and the amount of cold plate tubes 506 may equal the amount of single-sided DIMMs 502, which is eight in the example shown in FIG. 7. As the side of the single-sided DIMMs 502 that includes memory chips is the side facing the back toward the inlet 110 and the outlet 114, the single-sided DIMM 502 at the front does not have a cold plate tube 506 by its front side. The sockets 504 can include a locking mechanism, such as one or more latches, that move to a locked position when the single-sided DIMMs 502 are inserted into the sockets 504.

FIG. 8 illustrates an assembly process of the system 600 for double-sided DIMMs 602. At Stage 1, the cold plate tubes 606 are installed on the PCB 116. The sockets 604 for the double-sided DIMMs 602 are already attached to the PCB 116. As described herein, the double-sided DIMMs 602 may have a pitch of 0.257 inches or less. Each cold plate tube 606 has the gap pad 608, which can include the PMIC gap pad 406, on both planar surfaces 104 of the cold plate tube 606.

The cold plate tubes 606 are connected to the first manifold 108 and the second manifold 112 by the flexible hoses 120, and the sleeves 132 secure the ends of the flexible hoses 120 in place. For installing the first set of flexible hoses 120, first end of each flexible hose 120 can be connected to the first manifold 108 or the cold plate tube 606 by inserting the joint 128 of the first manifold 108 or the cold plate tube 606 into the first end of the flexible hose 120, as shown in FIG. 1A. A sleeve 132 can be fitted over the first end of each of the first set of flexible hoses 120 to secure the flexible hoses 120 in place. Another sleeve 132 can be fitted onto the second end of each first set of flexible hoses 120 and slid past the second end of the flexible hoses 120 as the joint 128 of the cold plate tube 606 or the first manifold 108 is inserted into the second end. Then the sleeve 132 can be slid forward over the second end of the flexible hose 120 to secure the second end in place. The same process can be performed for connecting the cold plate tubes 606 to the second manifold 112.

The first manifold 108 and the second manifold 112 are then fastened directly or indirectly to the PCB 116, being positioned in relation to the sockets 604 such that the double-sided DIMMs 602 would be positioned between the cold plate tubes 606. In some embodiments, the first manifold 108 and the second manifold 112 can be fastened to stands 118, which are in turn fastened to the PCB 116.

At Stage 2, a first double-sided DIMM 602 is inserted into the socket 604 between the back two cold plate tubes 606, which are the nearest cold plate tube 606 and the second nearest cold plate tube 606 to the inlet 110 and the outlet 114. As the DIMMs are double-sided, each double-sided DIMM 602 can be positioned between cold plate tubes 606 to cool both sides of the double-sided DIMM 602.

At Stage 3, the remaining double-sided DIMMs 602 are inserted into respective sockets 604 similarly to Stage 2. The cold plate tubes 606 and the double-sided DIMMs 602 are positioned in alternating order. It is understood that the double-sided DIMMs 602 can be inserted into their corresponding sockets 604 in any order and that the back double-sided DIMM 602 selected as the first for placement in Stage 2 is simply an illustrative example. As each double-sided DIMM 602 abuts a cold plate tube 606 on either side, the amount of cold plate tubes 606 may be one more than the amount of double-sided DIMMs 602. In the example shown in FIG. 8, the system 600 includes nine cold plate tubes 606 to cool eight double-sided DIMMs 602, where cold plate tubes 606 are at far ends to enclose the series of double-sided DIMMs 602. The sockets 604 can include a locking mechanism, such as one or more latches, that move to a locked position when the double-sided DIMMs 602 are inserted into the sockets 604.

At Stage 4, the clip 614 is fitted over a top portion of all cold plate tubes 606 and double-sided DIMMs 602. The clip 614 can include at least one set of teeth 802 along a width of the clip 614 for guiding the cold plate tubes 606 and gap pads 608 at the desired location during assembly and maintaining the proper location of the cold plate tubes 606 and gap pads 608 after assembly. The clip 614 can include a set of teeth 802 at both ends of the clip 614. At Stage 5, the system 600 assembly is complete.

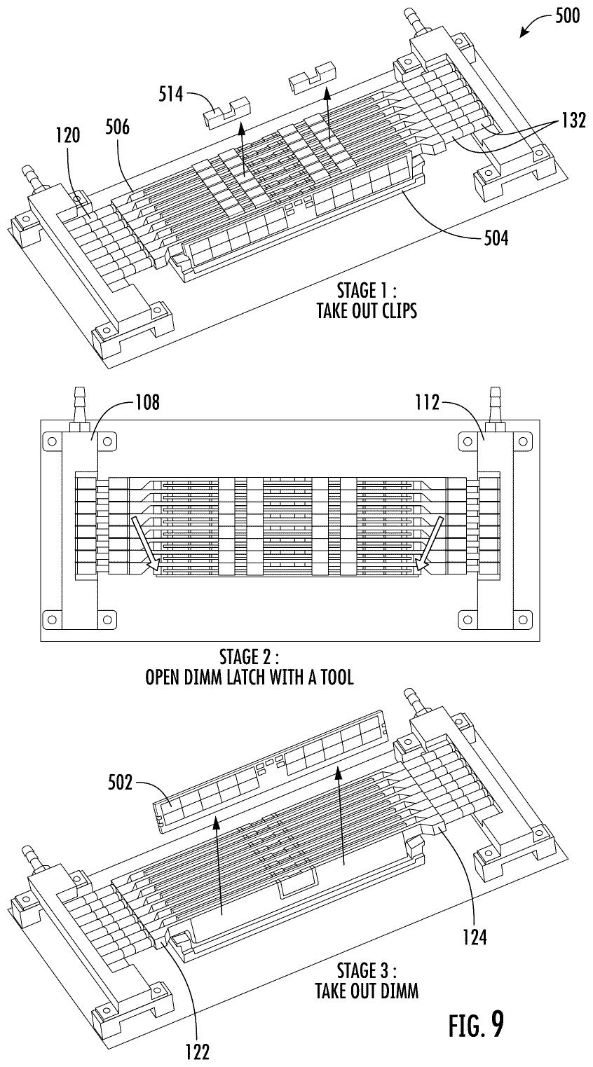

FIG. 9 illustrates a disassembly process of the cooling system 500 for single-sided DIMMs 502. At Stage 1, the clips 514 are removed from the pairs of cold plate tubes 506 and single-sided DIMMs 502. The clips 514 are removably attached and can be slid off the top portions of the cold plate tubes 506 and single-sided DIMMs 502. At Stage 2, the one or more latches on the sockets 504 are opened or disengaged to release the single-sided DIMMs 502, which may be performed by hand or with a tool such as a screwdriver. At Stage 3, the single-sided DIMMs 502 are removed from the sockets 504. It is understood that the disassembly process is similar for other types of memory modules discussed herein. For example, disassembling the cooling system 600 for double-sided DIMMs 602 includes removing the clip 614 from the cold plate tubes 606 and the double-sided DIMMs 602, opening the one or more latches on the sockets 604, and removing the double-sided DIMMs 602 from the sockets 604.

The sleeves 132 over the joints 128 of the first manifold 108 and the second manifold 112, shown in FIG. 1A, can be slid back on the flexible hoses 120 and the flexible hoses 120 can be removed from the first manifold 108 and the second manifold 112. The sleeves 132 over the joints of the first end 122 and the second end 124 of the cold plate tubes 102, which can include cold plate tubes 506 or cold plate tubes 606, can be slid back on the flexible hoses 120 and the flexible hoses 120 can be removed from the first end 122 and the second end 124. The flexible hoses 120 provide sufficient movement between the cold plate tubes 102 and the first manifold 108 and the second manifold 112 to remove the first ends 122 and the second ends 124 from the respective first manifold 108 and the second manifold 112. The cold plate tubes 102 can be removed for inspection, cleaning, maintenance, replacement, and the like of the memory modules. Individual one or more cold plate tubes 102 can be removed without removing all cold plate tubes 102 or the entire cooling architecture.

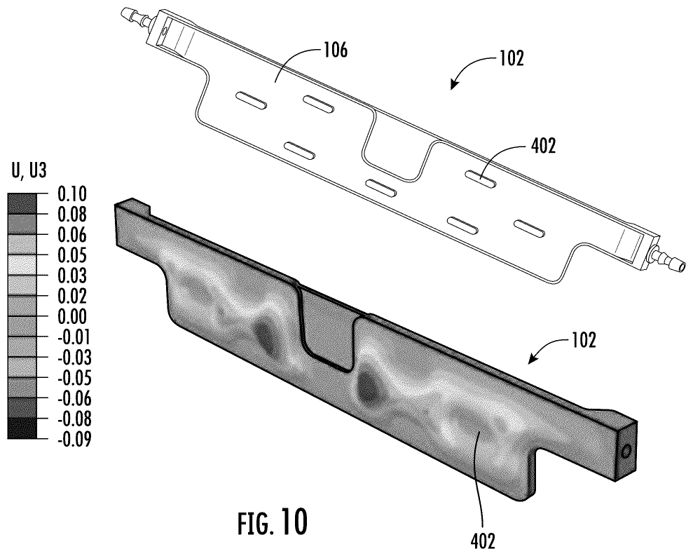

FIG. 10 illustrates a predicted maximum deformation of a cold plate tube with structural simulation. A Finite Element Analysis (FEA) was performed measuring the deformation or flexing of the cold plate tube 102 when 150 psi pressure is applied inside the cold plate tube 102. The embodiment of the cold plate tube 102 tested includes seven ribs 402 connecting covers 106 that each have a thickness of 0.4 mm. As described herein, the ribs 402 increase the structural integrity of the cold plate tube 102 and reduce the amount of deformation the covers 106 experience under pressure. The positions on the covers 106 where the ribs 402 are located experienced no deformation. According to the FEA, the cold plate tube 102 experience a maximum deformation of less than 0.1 mm when 150 psi pressure is applied inside the cold plate tube 102. FIG. 10 also illustrates an interior surface of the cover 106 of the cold plate tube 102 for reference, showing the positions of the ribs 402 extending from the interior surface of the cover 106.

### EXAMPLES

Example 1. An apparatus, comprising: a plurality of cold plate tubes spaced apart from each other, adjacent cold plate tubes defining a space for receiving a memory module, the plurality of cold plate tubes comprising thermally conductive material; a first manifold comprising an inlet for a cooling fluid; a second manifold comprising an outlet for the cooling fluid; a first plurality of flexible hoses for fastening a first end of the plurality of cold plate tubes to the first manifold; and a second plurality of flexible hoses for fastening a second end of the plurality of cold plate tubes to the second manifold.

Example 2. The apparatus of example 1, the first plurality of flexible hoses each removably attachable to a first joint extending from the first manifold and a second joint extending from the first end of the plurality of cold plate tubes, and the second plurality of flexible hoses are each removably attachable to a third joint extending from the second manifold and a fourth joint extending from the second end of the plurality of cold plate tubes.

Example 3. The apparatus of example 2 and any preceding example, further comprising a plurality of sleeves, the plurality of sleeves comprising an internal diameter larger than an external diameter of the first, second, third, and fourth joints, the plurality of sleeves configured to couple the flexible hoses to the first, second, third, and fourth joints, respectively.

Example 4. The apparatus of example 3 and any preceding example, the plurality of sleeves comprising a first set of the plurality of sleeves for securing the first plurality of flexible hoses to the first joints extending from the first manifold, a second set of the plurality of sleeves for securing the first plurality of flexible hoses to the second joints extending from the first end of the plurality of cold plate tubes, a third set of the plurality of sleeves for securing the second plurality of flexible hoses to the third joints extending from the second manifold, and a fourth set of the plurality of sleeves for securing the second plurality of flexible hoses to the fourth joints extending from the second end of the plurality of cold plate tubes.

Example 5. The apparatus of example 3 and any preceding example, the first, second, third, and fourth joints each comprising at least one barb extending from an outer surface of the respective joint.

Example 6. The apparatus of example 1 and any preceding example, with the first and second pluralities of flexible hoses fastened to the plurality of cold plate tubes and the respective first and second manifolds, the first and second pluralities of flexible hoses comprising a U-shape, with opposite ends of each of the first and second pluralities of U-shaped flexible hoses facing the plurality of cold plate tubes.

Example 7. The apparatus of example 1 and any preceding example, with the first and second pluralities of flexible hoses fastened to the plurality of cold plate tubes and the respective first and second manifolds, the first plurality of flexible hoses extending linearly from the first manifold to the plurality of cold plate tubes and the second plurality of flexible hoses extending linearly from the second manifold to the plurality of cold plate tubes.

Example 8. The apparatus of example 1 and any preceding example, the plurality of cold plate tubes each comprising opposite planar surfaces; and at least one rib internal to the cold plate tube and fastened to interior sides of the opposite planar surfaces.

Example 9. The apparatus of example 1 and any preceding example, the plurality of cold plate tubes each comprising at least one planar gap pad attached to a surface of the cold plate tube.

Example 10. An apparatus, comprising: a plurality of cold plate tubes equally spaced apart from each other, adjacent cold plate tubes defining a space for receiving a memory module, the plurality of cold plate tubes comprising thermally conductive material; a first manifold comprising an inlet for a cooling fluid, the plurality of cold plate tubes removably attachable to the first manifold; and a second manifold comprising an outlet for the cooling fluid, the plurality of cold plate tubes removably attachable to the second manifold.

Example 11. The apparatus of example 10 and any preceding example, the plurality of cold plate tubes equally spaced for receiving a Dual-Inline Memory Module (DIMM) between each adjacent cold plate tube.

Example 12. The apparatus of example 11 and any preceding example, the plurality of cold plate tubes equally spaced for receiving a single-sided DIMM between each adjacent cold plate tube.

Example 13. The apparatus of example 11 and any preceding example, the plurality of cold plate tubes equally spaced for receiving a double-sided DIMM between each adjacent cold plate tube.

Example 14. The apparatus of example 13 and any preceding example, comprising a clip for securing the plurality of cold plate tubes and the plurality of double-sided DIMMs together, the clip comprising a plurality of teeth extending from the clip for locating the plurality of cold plate tubes.

Example 15. The apparatus of example 10 and any preceding example, the plurality of cold plate tubes each comprising: opposite planar surfaces; and at least one rib internal to the cold plate tube and fastened to interior sides of the opposite planar surfaces.

Example 16. The apparatus of example 10 and any preceding example, comprising: a first plurality of flexible hoses each removably attachable to a first joint extending from the first manifold and a second joint extending from the first end of the plurality of cold plate tubes; and a second plurality of flexible hoses each removably attachable to a third joint extending from the second manifold and a fourth joint extending from the second end of the plurality of cold plate tubes.

Example 17. An apparatus, comprising: a body comprising thermally conductive material, the body comprising: a first planar surface; a second planar surface opposite the first planar surface; an inlet for a cooling fluid at a first end of the body; an outlet for the cooling fluid at a second end of the body; at least one internal rib fastened to an interior side of the first planar surface and an interior side of the second planar surface.

Example 18. The apparatus of example 17 and any preceding example, the inlet comprising a barb extending from the inlet, the outlet comprising a barb extending from the outlet.

Example 19. The apparatus of example 17 and any preceding example, a cross-section of the at least one internal rib comprising an elongated shape.

Example 20. The apparatus of example 17 and any preceding example, the body comprising a gap pad on the first planar surface and/or the second planar surface, the gap pad comprising thermal interface material layer.

What is claimed is:

1. An apparatus, comprising:
a plurality of cold plate tubes spaced apart from each other, adjacent cold plate tubes defining a space for receiving a memory module, the plurality of cold plate tubes comprising thermally conductive material;
a first manifold comprising an inlet for a cooling fluid;
a second manifold comprising an outlet for the cooling fluid;
a first plurality of flexible hoses for fastening a first end of the plurality of cold plate tubes to the first manifold; and
a second plurality of flexible hoses for fastening a second end of the plurality of cold plate tubes to the second manifold.

2. The apparatus of claim 1, the first plurality of flexible hoses each removably attachable to a first joint extending from the first manifold and a second joint extending from the first end of the plurality of cold plate tubes, and the second plurality of flexible hoses are each removably attachable to a third joint extending from the second manifold and a fourth joint extending from the second end of the plurality of cold plate tubes.

3. The apparatus of claim 2, further comprising a plurality of sleeves, the plurality of sleeves comprising an internal diameter larger than an external diameter of the first, second, third, and fourth joints, the plurality of sleeves configured to couple the flexible hoses to the first, second, third, and fourth joints, respectively.

4. The apparatus of claim 3, the plurality of sleeves comprising a first set of the plurality of sleeves for securing the first plurality of flexible hoses to the first joints extending from the first manifold, a second set of the plurality of sleeves for securing the first plurality of flexible hoses to the second joints extending from the first end of the plurality of cold plate tubes, a third set of the plurality of sleeves for securing the second plurality of flexible hoses to the third joints extending from the second manifold, and a fourth set of the plurality of sleeves for securing the second plurality of flexible hoses to the fourth joints extending from the second end of the plurality of cold plate tubes.

5. The apparatus of claim 3, the first, second, third, and fourth joints each comprising at least one barb extending from an outer surface of the respective joint.

6. The apparatus of claim 1, with the first and second pluralities of flexible hoses fastened to the plurality of cold plate tubes and the respective first and second manifolds, the first and second pluralities of flexible hoses comprising a U-shape, with opposite ends of each of the first and second pluralities of U-shaped flexible hoses facing the plurality of cold plate tubes.

7. The apparatus of claim 1, with the first and second pluralities of flexible hoses fastened to the plurality of cold plate tubes and the respective first and second manifolds, the first plurality of flexible hoses extending linearly from the first manifold to the plurality of cold plate tubes and the second plurality of flexible hoses extending linearly from the second manifold to the plurality of cold plate tubes.

8. The apparatus of claim 1, the plurality of cold plate tubes each comprising opposite planar surfaces; and at least one rib internal to the cold plate tube and fastened to interior sides of the opposite planar surfaces.

9. The apparatus of claim 1, the plurality of cold plate tubes each comprising at least one planar gap pad attached to a surface of the cold plate tube.

10. An apparatus, comprising:
a plurality of cold plate tubes equally spaced apart from each other, adjacent cold plate tubes defining a space for receiving a memory module, the plurality of cold plate tubes comprising thermally conductive material;
a first manifold comprising an inlet for a cooling fluid, the plurality of cold plate tubes removably attachable to the first manifold; and
a second manifold comprising an outlet for the cooling fluid, the plurality of cold plate tubes removably attachable to the second manifold.

11. The apparatus of claim 10, the plurality of cold plate tubes equally spaced for receiving a Dual-Inline Memory Module (DIMM) between each adjacent cold plate tube.

12. The apparatus of claim 11, the plurality of cold plate tubes equally spaced for receiving a single-sided DIMM between each adjacent cold plate tube.

13. The apparatus of claim 11, the plurality of cold plate tubes equally spaced for receiving a double-sided DIMM between each adjacent cold plate tube.

14. The apparatus of claim 13, comprising a clip for securing the plurality of cold plate tubes and the plurality of double-sided DIMMs together, the clip comprising a plurality of teeth extending from the clip for locating the plurality of cold plate tubes.

15. The apparatus of claim 10, the plurality of cold plate tubes each comprising:
opposite planar surfaces; and
at least one rib internal to the cold plate tube and fastened to interior sides of the opposite planar surfaces.

16. The apparatus of claim 10, comprising:
a first plurality of flexible hoses each removably attachable to a first joint extending from the first manifold and a second joint extending from the first end of the plurality of cold plate tubes; and
a second plurality of flexible hoses each removably attachable to a third joint extending from the second manifold and a fourth joint extending from the second end of the plurality of cold plate tubes.

17. An apparatus, comprising:
a body comprising thermally conductive material, the body comprising:
a first planar surface;
a second planar surface opposite the first planar surface;
an inlet for a cooling fluid at a first end of the body;
an outlet for the cooling fluid at a second end of the body;
at least one internal rib fastened to an interior side of the first planar surface and an interior side of the second planar surface.

18. The apparatus of 17, the inlet comprising a barb extending from the inlet, the outlet comprising a barb extending from the outlet.

19. The apparatus of claim 17, a cross-section of the at least one internal rib comprising an elongated shape.

20. The apparatus of claim 17, the body comprising a gap pad on the first planar surface and/or the second planar surface, the gap pad comprising thermal interface material layer.
